(19) United States
(12) Patent Application Publication
(10) Pub. No.: US 2018/0033961 A1
(43) Pub. Date: Feb. 1, 2018

(54) SEMICONDUCTOR DEVICE AND MANUFACTURING METHOD THEREOF

(71) Applicant: UNITED MICROELECTRONICS CORP., Hsinchu (TW)

(72) Inventors: Liang Yi, Singapore (SG); Chia-Ching Hsu, Lunbei Township (TW); Shen-De Wang, Zhudong Township (TW); Ko-Chi Chen, Taoyuan City (TW)

(21) Appl. No.: 15/260,754

(22) Filed: Sep. 9, 2016

(30) Foreign Application Priority Data
Jul. 29, 2016 (CN) 201610614946.6

(51) Int. Cl. H01L 45/00; H01L 27/24

(52) U.S. Cl. CPC H01L 45/1293; H01L 45/085; H01L 45/1233; H01L 45/1266; H01L 45/145; H01L 45/1608; H01L 45/1666; H01L 27/2436

(57) ABSTRACT

A semiconductor device and a manufacturing method thereof are provided. The semiconductor device includes a substrate, a bottom metal layer, a resistive random access memory (ReRAM) cell structure, and an upper metal layer. The bottom metal layer is located above the substrate. The ReRAM cell structure is formed on the bottom metal layer. The ReRAM cell structure includes a bottom electrode, a memory cell layer, a top electrode, and a spacer. The memory cell layer is formed on the bottom electrode. The top electrode is formed on the memory cell layer. The spacer is formed on two sides of the bottom electrode, the memory cell layer and the top electrode. The upper metal layer is electrically connected to and directly contacting the top electrode.

This application claims the benefit of People's Republic of China application Serial No. 201610614946.6, filed Jul. 29, 2016, the subject matter of which is incorporated herein by reference.

### BACKGROUND

### Technical Field

The present disclosure relates in general to a semiconductor device and a manufacturing method thereof, and more particularly to a semiconductor device having a resistive random access memory (ReRAM) cell structure and a manufacturing method thereof.

### Description of the Related Art

ReRAM devices have advantages of such as simple structures, low operating voltages, and high compatibility with current CMOS manufacturing processes, and therefore are often used in storage devices.

Moreover, in accordance with the current trend where components having deferent functions are to be integrated into a single device, integration of ReRAM components into other devices or the manufacture and improvements of the manufacturing process thereof have become main research topics for industry.

### SUMMARY OF THE INVENTION

The present disclosure is directed to a semiconductor device and a manufacturing method thereof. According to the embodiments of the semiconductor device and the manufacturing method thereof, the upper metal layer is electrically connected to and directly contacts the top electrode of the ReRAM cell structure; in other words, the manufacturing of the ReRAM cell structure is substantially integrated into the copper manufacturing process of the metal layers, such that the whole size of the semiconductor device can be effectively reduced.

According to an embodiment of the present disclosure, a semiconductor device is disclosed. The semiconductor device includes a substrate, a bottom metal layer, a resistive random access memory (ReRAM) cell structure, and an upper metal layer. The bottom metal layer is located above the substrate. The ReRAM cell structure is formed on the bottom metal layer. The ReRAM cell structure includes a bottom electrode, a memory cell layer, a top electrode, and a spacer. The memory cell layer is formed on the bottom electrode. The top electrode is formed on the memory cell layer. The spacer is formed on two sides of the bottom electrode, the memory cell layer and the top electrode. The upper metal layer is electrically connected to and directly contacting the top electrode.

According to another embodiment of the present disclosure, a semiconductor device is disclosed. The semiconductor device includes a substrate, a bottom metal layer, a plurality of ReRAM cell structures, an upper metal layer, and an air gap. The bottom metal layer is located above the substrate. The ReRAM cell structures are formed on the bottom metal layer. Each of the ReRAM cell structures includes a bottom electrode, a memory cell layer and a top electrode. The memory cell layer is formed on the bottom electrode. The top electrode is formed on the memory cell layer. The upper metal layer is electrically connected to and directly contacting the top electrode. The air gap is formed between the adjacent ReRAM cell structures.

According to a further embodiment of the present disclosure, a manufacturing method of a semiconductor device is disclosed. The manufacturing method of the semiconductor device includes the following steps: providing a substrate; forming a bottom metal layer above the substrate; forming a ReRAM cell structure on the bottom metal layer, comprising: forming a bottom electrode; forming a memory cell layer on the bottom electrode; forming a top electrode on the memory cell layer; and forming a spacer on two sides of the bottom electrode, the memory cell layer and the top electrode; and forming an upper metal layer electrically connected to and directly contacting the top electrode.

The disclosure will become apparent from the following detailed description of the preferred but non-limiting embodiments. The following description is made with reference to the accompanying drawings.

### BRIEF DESCRIPTION OF THE DRAWINGS

FIG. 1 is a schematic view of a semiconductor device according to an embodiment of the present disclosure;

FIG. 2 is a top view of a semiconductor device according to another embodiment of the present disclosure;

FIG. 2A is a cross-sectional view along the cross-section line 2A-2A′ in FIG. 2;

FIG. 2B is a cross-sectional view along the cross-section line 2B-2B′ in FIG. 2;

FIG. 3 is a schematic view of a semiconductor device according to a further embodiment of the present disclosure; and

FIGS. 4-9B show a manufacturing process of a semiconductor device according to an embodiment of the present disclosure.

### DETAILED DESCRIPTION OF THE INVENTION

According to the embodiments of the present disclosure, a semiconductor device and a manufacturing method thereof are provided. In the embodiments, the upper metal layer is electrically connected to and directly contacts the top electrode of the ReRAM cell structure; in other words, the manufacturing of the ReRAM cell structure is substantially integrated into the copper manufacturing process of the metal layers, such that the whole size of the semiconductor device can be effectively reduced. The embodiments are described in details with reference to the accompanying drawings. The procedures and details of the manufacturing method and the structure of the embodiments are for exemplification only, not for limiting the scope of protection of the disclosure. Moreover, the identical or similar elements of the embodiments are designated with the same reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense. It is to be noted that the drawings are simplified for clearly describing the embodiments, and the details of the structures of the embodiments are for exemplification only, not for limiting the scope of protection of the disclosure. Ones having ordinary skills in the art may modify or change the structures according to the embodiments of the present disclosure.

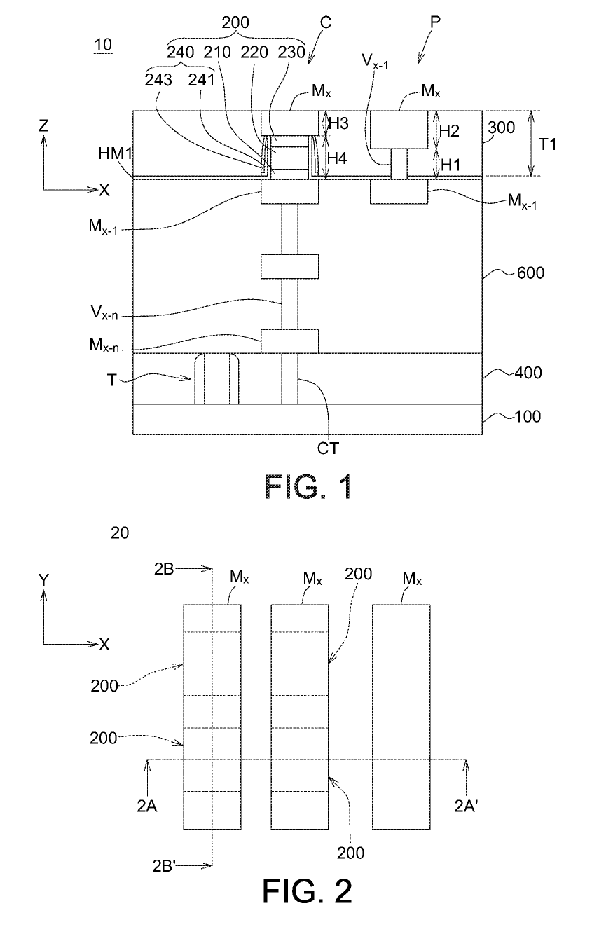

FIG. 1 is a schematic view of a semiconductor device 10 according to an embodiment of the present disclosure. As shown in FIG. 1, the semiconductor device 10 includes a substrate 100, a bottom metal layer Mₓ₋₁, a resistive random access memory (ReRAM) cell structure 200, and an upper metal layer Mₓ. The bottom metal layer Mₓ₋₁ is located above the substrate 100. The ReRAM cell structure 200 is formed on the bottom metal layer Mₓ₋₁. The ReRAM cell structure 200 includes a bottom electrode 210, a memory cell layer 220, and a top electrode 230. The memory cell layer 220 is formed on the bottom electrode 210. The top electrode 230 is formed on the memory cell layer 220. The upper metal layer Mₓ is electrically connected to the top electrode 230 and directly contacting the top electrode 230.

According to the embodiments of the present disclosure, the upper metal layer Mₓ is electrically connected to and directly contacts the top electrode 230 of the ReRAM cell structure 200; in other words, the manufacturing of the ReRAM cell structure 200 is substantially integrated into the copper manufacturing process of the metal layers, such that the whole size of the semiconductor device can be effectively reduced.

In an embodiment, the semiconductor device 10 is such as a ReRAM device.

In some embodiments, as shown in FIG. 1, the ReRAM cell structure 200 may further include a spacer 240. As shown in FIG. 1, the spacer 240 is formed on two sides of the bottom electrode 210, the memory cell layer 220 and the top electrode 230. For example, the spacer 240 as shown in FIG. 1 may include a silicon oxide layer 241 and a silicon nitride layer 243. However, the selections of the material of the spacer 240 may vary according to actual needs, such as a silicon oxide layer or a silicon nitride layer, and is not limited thereto.

In some embodiments, as shown in FIG. 1, the semiconductor device 10 may further include an inter-metal dielectric (IMD) 300. As shown in FIG. 1, the inter-metal dielectric 300 is formed on the bottom metal layer Mₓ₋₁, and the ReRAM cell structure 200 and the upper metal layer Mₓ are formed within the inter-metal dielectric 300.

In the embodiment, the inter-metal dielectric 300 has a thickness T1 of such as 2500-3500 Å.

In some embodiments, as shown in FIG. 1, the semiconductor device 10 may further include a via Vₓ₋₁. As shown in FIG. 1, the via Vₓ₋₁ is formed in the inter-metal dielectric 300 and located at a lateral side of the ReRAM cell structure 200. The upper metal layer Mₓ is electrically connected to the bottom metal layer Mₓ₋₁ through the via Vₓ₋₁.

In the embodiment, the via Vₓ₋₁ has a height H1 of such as 1000-1500 Å. For example, in an embodiment, the height H1 of the via Vₓ₋₁ is such as 1250 Å.

As shown in FIG. 1, the semiconductor device 10 may have a memory cell area C and a peripheral circuit area P. The upper metal layer Mₓ of the peripheral circuit area P is electrically connected to the bottom metal layer Mₓ₋₁ through the via Vₓ₋₁. There is no via disposed between the upper metal layer Mₓ of the memory cell area C and the ReRAM cell structure 200. The upper metal layer Mₓ of the memory cell area C directly contacts the top electrode 230 of the ReRAM cell structure 200 to achieve the electrical connection.

In the embodiment, the upper metal layer Mₓ of the peripheral circuit area P has a height H2 that is for example larger than the height H3 of the upper metal layer Mₓ of the memory cell area C. For example, in an embodiment, the height H2 of the upper metal layer Mₓ of the peripheral circuit area P is such as 1600 Å, the height H3 of the upper metal layer Mₓ of the memory cell area C is such as 1350 Å, and the height H4 of the ReRAM cell structure 200 is such as 1500 Å.

In some embodiments, as shown in FIG. 1, the semiconductor device 10 may further include an interlayer dielectric (ILD) 400, at least a transistor T, and at least a contact CT. The interlayer dielectric 400 is formed on the substrate 100. The transistor T and the contact CT are formed on the substrate 100 and located in the interlayer dielectric 400. The transistor T is used to control the access of the ReRAM cell structure 200. In the embodiment, the material of the contact CT includes such as tungsten (W).

In some embodiments, as shown in FIG. 1, the semiconductor device 10 may further include a dielectric layer 600 located between the inter-metal dielectric 300 and the interlayer dielectric 400. In the embodiment, the semiconductor device 10 may further include at least a metal layer Mₓ₋ₙ and at least a via Vₓ₋ₙ. The metal layer Mₓ₋ₙ and the via Vₓ₋ₙ are located in the dielectric layer 600, and the metal layer Mₓ₋ₙ and the via Vₓ₋ₙ are located between the bottom metal layer Mₓ₋₁ and the substrate 100. The metal layer Mₓ₋ₙ is electrically connected to the bottom metal layer Mₓ₋₁ through the via Vₓ₋ₙ.

In some embodiments, the materials of the upper metal layer Mₓ, the via Vₓ₋₁, the bottom metal layer Mₓ₋₁, the metal layer Mₓ₋ₙ, and the via Vₓ₋ₙ are such as copper. According to the embodiments of the present disclosure, the manufacturing of the ReRAM cell structure 200 is substantially integrated into the copper manufacturing processes of the above-mentioned metal layers and vias, such that the whole size of the semiconductor device can be effectively reduced.

In some embodiments, as shown in FIG. 1, the semiconductor device 10 may further include a hard mask layer HM1 formed on the ReRAM cell structure 200 and the dielectric layer 600.

In some embodiments, the bottom electrode 210 and the top electrode 230 may respectively include Ti, TiN, Ta, TaN, Pt, W, Al, Cu or any combination thereof.

In some embodiments, the material of the memory cell layer 220 may include HfOₓ, TaOₓ, TiOₓ, ZnOₓ, WOₓ, GdOₓ, IGZO, PCMO, CeOₓ, BaTiOₓ, VOₓ, HfSiOₓ, Si, BST, HoOₓ, SrZrOₓ, AlNₓ, BaTiOF₄, BON, CoOₓ, GaV₄S₈, InOₓ, LaOₓ, NiN, SmOₓ, SiOₓ, NiOₓ, AlOₓ, graphene, BiFeO₃, NbOₓ, SrTiOₓ, SiNₓ, CuOₓ, ZrOₓ, LSMO, ZrTiOₓ, CuSiOₓ, LaGdOₓ, WSiOₓ, BaSrTiOₓ, BiTiOₓ, carbon nanotubes (CNT), GaOₓ, GeS, LaAlOₓ, MgOₓ, silk, TaON, suitable organic material, or any combinations thereof.

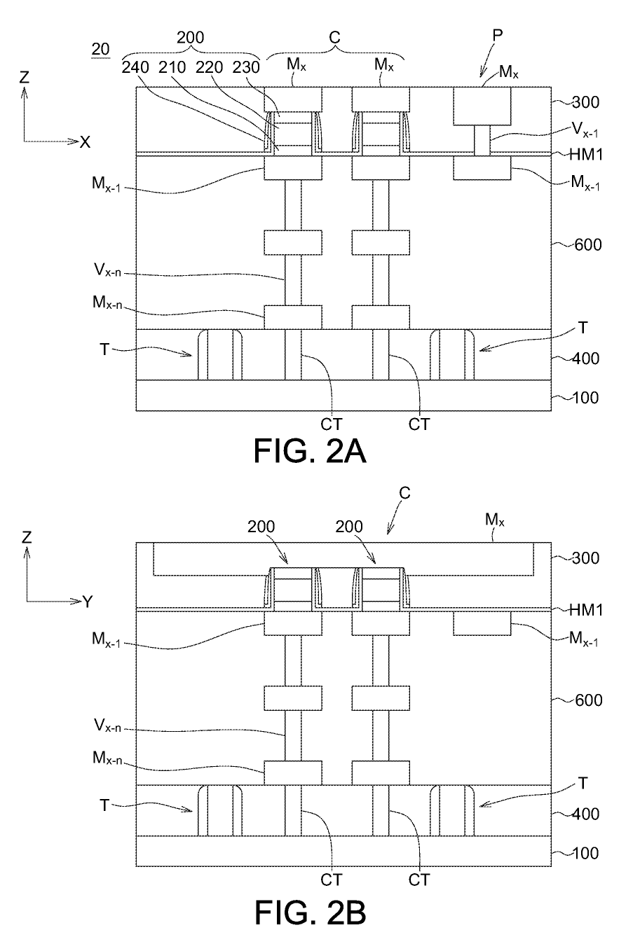

FIG. 2 is a top view of a semiconductor device 20 according to another embodiment of the present disclosure, FIG. 2A is a cross-sectional view along the cross-section line 2A-2A′ in FIG. 2, and FIG. 2B is a cross-sectional view along the cross-section line 2B-2B′ in FIG. 2. The elements in the present embodiment sharing similar or the same labels with those in the previous embodiment are similar or the same elements, and the description of which is omitted.

As shown in FIGS. 2 and 2A-2B, the semiconductor device 20 may include a plurality of ReRAM cell structures 200. The ReRAM cell structures 200 are formed on the bottom metal layer Mₓ₋₁, and each of the ReRAM cell structures 200 includes the bottom electrode 210, the memory cell layer 220, and the top electrode 230 as above-mentioned.

As shown in FIGS. 2A-2B, the semiconductor device 20 may include the spacer 240 formed on two sides of each of the ReRAM cell structures 200. In the embodiment, the spacer 240 is formed on two sides of the bottom electrode 210, the memory cell layer 220, and the top electrode 230 of each of the ReRAM cell structures 200.

As shown in FIGS. 2A-2B, the upper metal layer Mₓ electrically connects the ReRAM cell structures 200 along the Y direction. The ReRAM cell structures 200 along the X direction are not electrically connected through the upper metal layer Mₓ.

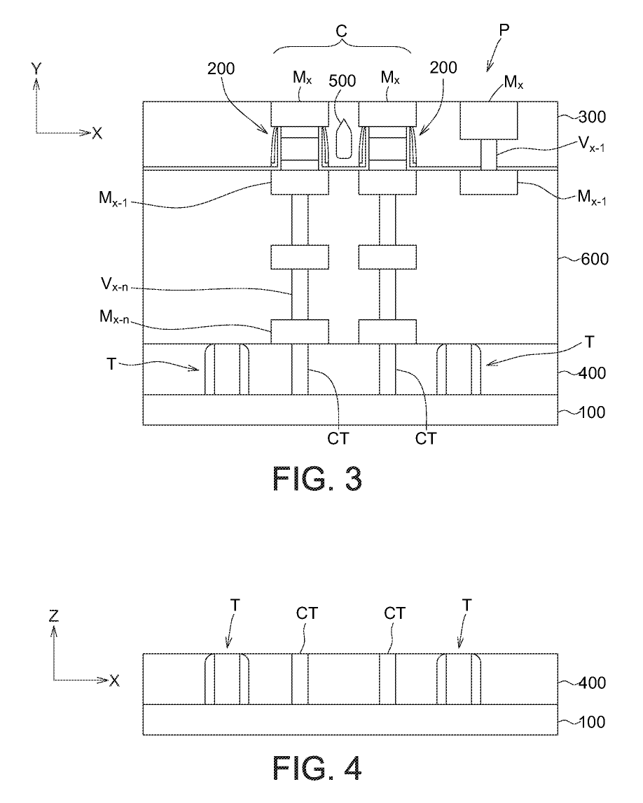

FIG. 3 is a schematic view of a semiconductor device 30 according to a further embodiment of the present disclosure. The elements in the present embodiment sharing similar or the same labels with those in the previous embodiments are similar or the same elements, and the description of which is omitted.

As shown in FIG. 3, the semiconductor device 30 may include at least an air gap 500. The air gap 500 is formed between the adjacent ReRAM cell structures 200.

When a current drives the ReRAM cell structure 200 to perform operations, the material of the memory cell layer 220 would release heat. For example, when a memory cell layer 220 of one ReRAM cell structure 200 performs a write operation, and if the material of the memory cell layer 220 releases too much heat, then the diffused heat may easily influence the material of the memory cell layer 220 of an adjacent ReRAM cell structure 200. Such released and diffused heat may possibly transform the material state of the influenced memory cell layer 220 of the adjacent ReRAM cell structure 200, rendering the originally no-to-be-written adjacent memory cell layer 220 to be written, for example, the state may transform from “1” to “0” or from “0” to “1”. On the contrary, according to the embodiments of the present disclosure, the air gap 500 is formed between adjacent ReRAM cell structures 200, and the air in the air gap 500 transmits heat slower than the dielectric material of the inter-metal dielectric 300 does. For example, the thermal conductivity coefficient of air is about 0.02, and the thermal conductivity coefficient of silicon oxide is about 1. As such, the air gap 500 can reduce the heat transmission between adjacent ReRAM cell structures 200, and thus can prevent the operation failures of memory cell devices (semiconductor device 30).

Furthermore, if the heat transmission between adjacent memory cell devices is to be reduced by enlarging the widths of the memory cells, such that the size changes of the memory cells would influence the operation performances of the memory cell devices, and the enlarged widths would cause the size of the memory cell devices to increase as well. On the contrary, according to the embodiments of the present disclosure, the air gap 500 between adjacent ReRAM cell structures 200 is utilized to reduce heat transmission, such that the sizes of the memory cell devices (semiconductor device 300) are not changed, operation failures can be prevented, and the reliability of the memory cell devices (semiconductor device 300) can be further enhanced.

FIGS. 4-9B show a manufacturing process of a semiconductor device according to an embodiment of the present disclosure. The elements in the present embodiment sharing similar or the same labels with those in the previous embodiments are similar or the same elements, and the description of which is omitted.

Please refer to FIG. 4, a substrate 100 is provided.

As shown in FIG. 4, at least a transistor T and at least a contact CT may be formed on the substrate 100. Next, an interlayer dielectric 400 is formed on the substrate 100, and the transistor T and the contact CT are located in the interlayer dielectric 400.

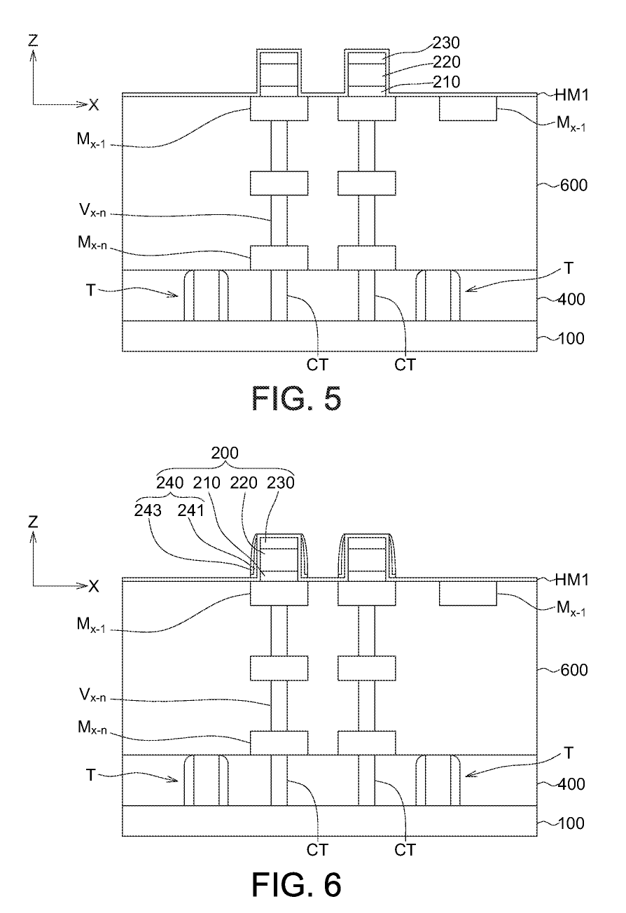

Next, as shown in FIG. 5, a dielectric layer 600, a bottom metal layer Mₓ₋₁, at least one metal layer Mₓ₋ₙ, and at least one via Vₓ₋ₙ are formed above the substrate 100.

Next, as shown in FIG. 5, the top surface of the bottom metal layer Mₓ₋₁ is planarized by such as a CMP process, and then the ReRAM cell structure 200 is formed on the bottom metal layer Mₓ₋₁. The manufacturing process of forming the ReRAM cell structure 200 may include forming a bottom electrode 210, forming a memory cell layer 220 on the bottom electrode 210, and forming a top electrode 230 on the memory cell layer 220.

In the embodiment, the manufacturing process of forming the bottom electrode 210, the memory cell layer 220, and the top electrode 230 may include the following steps. First, a bottom electrode material is formed, then a memory cell material is formed on the bottom electrode material, and then the bottom electrode material, the memory cell material, and the top electrode material are patterned by an etching process for forming the bottom electrode 210, the memory cell layer 220, and the top electrode 230.

Next, as shown in FIG. 5, a hard mask layer HM1 may be formed on the ReRAM cell structure 200 and the dielectric layer 600. In the embodiment, the hard mask layer HM1 is such as a silicon nitride layer.

Next, as shown in FIG. 6, a spacer 240 may be formed on two sides of the bottom electrode 210, the memory cell layer 220, and the top electrode 230.

In the embodiment, the manufacturing process of forming the spacer 240 may include such as the following steps. A spacer material is deposited on the bottom electrode 210, the memory cell layer 220, and the top electrode 230, and then the spacer material is etched for forming the spacer 240 on the two sides of the bottom electrode 210, the memory cell layer 220, and the top electrode 230. In the embodiment, the space material may include a silicon oxide material layer and a silicon nitride material layer, and these two layers respectively form a silicon oxide layer 241 and a silicon nitride layer 243 after the etching process.

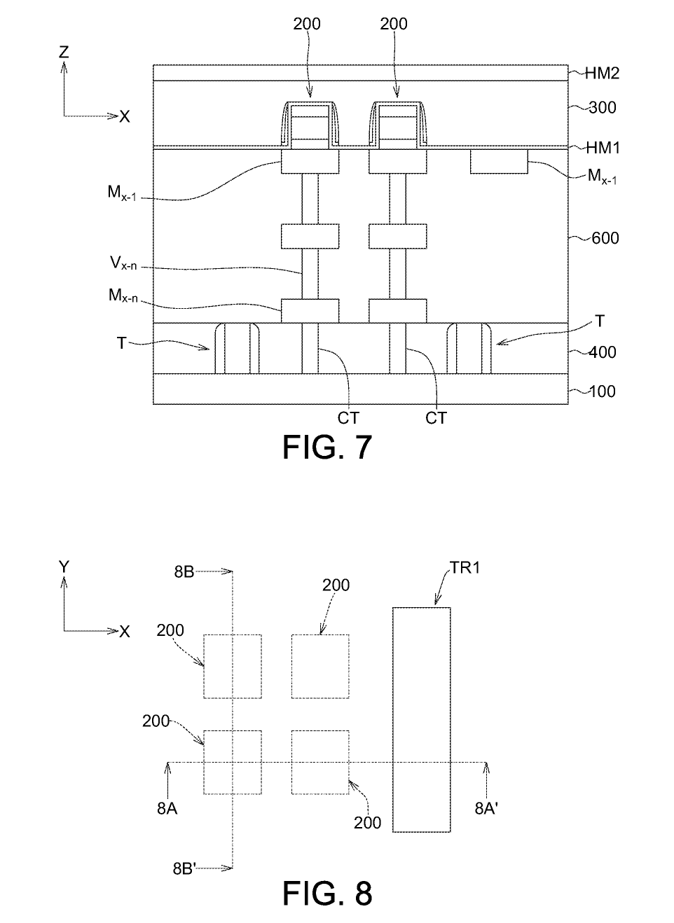

Next, as shown in FIG. 7, an inter-metal dielectric 300 is formed on the bottom metal layer Mₓ₋₁ and the hard mask layer HM1, and the ReRAM cell structure 200 is formed within the inter-metal dielectric 300. In the embodiment, a dielectric material is formed on the bottom metal layer Mₓ₋₁, and then the surface of the dielectric material is planarized by such as a CMP process to form the inter-metal dielectric 300. The thickness of the inter-metal dielectric 300 is such as 2500-3500 Å.

Next, as shown in FIG. 7, another hard mask layer HM2 may be formed on the inter-metal dielectric 300. In the embodiment, the hard mask layer HM2 is such as a silicon oxide layer.

Next, as shown in FIGS. 2-2B and 8-9B, a via Vₓ₋₁ is formed in the inter-metal dielectric 300 and located at a lateral side of the ReRAM cell structure 200, and an upper metal layer Mₓ is formed in the inter-metal dielectric 300. As shown in FIGS. 2-2B, the as-formed upper metal layer Mₓ is electrically connected to the bottom metal layer Mₓ₋₁ through the via Vₓ₋₁, and the upper metal layer Mₓ is electrically connected to the top electrode 230 and directly contacts the top electrode 230. The via Vₓ₋₁ has a height of about 1000-1500 Å.

In the embodiment, the manufacturing processes of forming the upper metal layer Mₓ and forming the via Vₓ₋₁ may include such as the following steps.

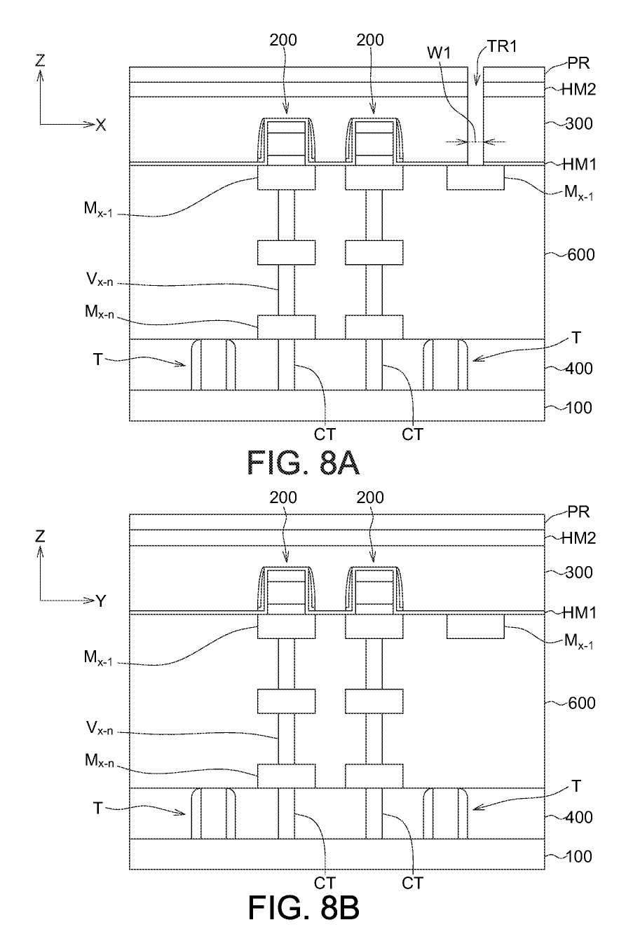

Please refer to FIGS. 8 and 8A-8B. FIG. 8 shows a top view of a step in a manufacturing process of a semiconductor device according to an embodiment of the present disclosure, FIG. 8A is a cross-sectional view along the cross-section line 8A-8A′ in FIG. 8, and FIG. 8B is a cross-sectional view along the cross-section line 8B-8B′ in FIG. 8.

As shown in FIGS. 8 and 8A-8B, a patterned photoresist layer PR is formed on the hard mask layer HM2, and an etching process is performed according to the patterned photoresist layer PR to remove a portion of the hard mask layer HM2, a portion of the inter-metal dielectric 300, and a portion of the hard mask HM1, for exposing a portion of the surface of the bottom metal layer Mₓ₋₁ and forming a trench TR1. The width W1 of the trench TR1 is substantially the same with the width of the via Vₓ₋₁ which will be formed subsequently. In the present step, the ReRAM cell structure 200 is still covered by the inter-metal dielectric 300. In other words, the trench TR1 is only formed above the bottom metal layer Mₓ₋₁ of the peripheral circuit area P.

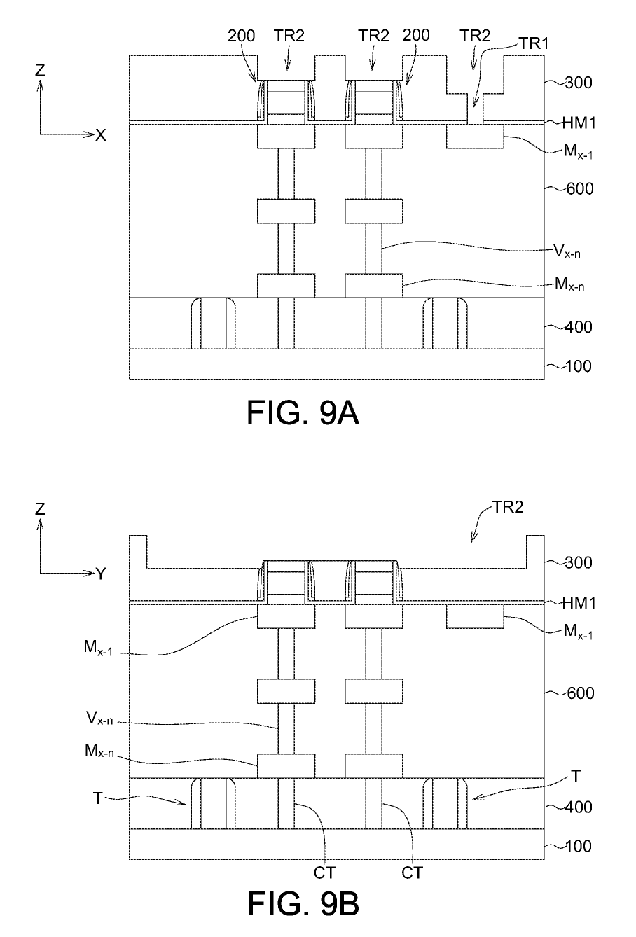

Please refer to FIGS. 9A-9B. FIGS. 9A-9B show cross-sectional views of another step in a manufacturing process of a semiconductor device according to an embodiment of the present disclosure.

As shown in FIGS. 9A-9B, an etching process is performed according to another patterned photoresist (not shown) to remove a portion of the hard mask layer HM2, a portion of the inter-metal dielectric 300, and a portion of the hard mask HM1, for exposing a portion of the surface of the top electrode 230 and forming a trench TR2 above the trench TR1. The top view pattern of the trench TR2 is substantially the same with the top view pattern of the upper metal layer Mₓ which will be formed subsequently. The above-described manufacturing process applies a via-first process to form the upper metal layer Mₓ and the via Vₓ₋₁. In other embodiments, the upper metal layer Mₓ and the via Vₓ₋₁ may be formed by a via-last process as well, not limited to the above-described process.

Next, please refer to FIGS. 2-2B, a metal material is filled into the trench TR1 and the trench TR2 for forming the via Vₓ₋₁ and the upper metal layer Mₓ. As such, the semiconductor device 20 as shown in FIGS. 2-2B is formed.

Specifically speaking, the trench TR1 located above the bottom metal layer Mₓ₋₁ of the peripheral circuit area P is filled with a metal material to form the via Vₓ₋₁, and the trench TR2 is filled with a metal material to form the upper metal layer Mₓ. As a result, since the via Vₓ₋₁ is only formed in the peripheral circuit area P, such that the manufacturing process of the via does not influence the manufacturing processes and the structures in other areas. The ReRAM cell structure 200 in the memory cell area C does not require the manufacturing of any via and is directly electrically connected to the upper metal layer Mₓ through the top electrode 230, thereby the whole manufacturing process can be simplified. In addition, a height that could've possibly generated from a via has been omitted, therefore the size of the semiconductor device is reduced along the vertical direction. Furthermore, the via of the present disclosure has a relatively small height, as such the width of the via is relatively small accordingly, as such, the size of the semiconductor device is reduced along the horizontal direction as well.

The manufacturing method of the semiconductor device 30 as shown in FIG. 3 is similar to that of the semiconductor device 20 as aforementioned. Please refer to FIGS. 5-6, by controlling the height and the width of the trench between two adjacent ReRAM cell structures 200, an air gap 500 can be formed when filling a dielectric material into the trench. For example, the distance between two spacers 240 can be further controlled by controlling and adjusting the thicknesses of the spacers 240, rendering the trench between two ReRAM cell structures 200 having a relatively large aspect ratio. As such, the formation of the air gap 500 can be controlled in the process of filling the dielectric material without requiring disposing additional hard mask layer(s).

In some embodiments, in the manufacturing process of the semiconductor device 30, the dielectric material used for forming the inter-metal dielectric 300 can be preferably a dielectric material of a poorer gap fill capability. In the embodiment, the dielectric material may be for example a low-K material or fluorinated silicon oxide (FSG).

In some embodiments, the aspect ratio (height/width) of the trench between two adjacent ReRAM cell structures 200 may be such as larger than 0.5, preferably may be larger than 1, and preferably may be for example larger than 3.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a bottom metal layer located above the substrate;
a resistive random access memory (ReRAM) cell structure formed on the bottom metal layer, comprising:
a bottom electrode;
a memory cell layer formed on the bottom electrode;
a top electrode formed on the memory cell layer; and
a spacer formed on two sides of the bottom electrode, the memory cell layer and the top electrode; and
an upper metal layer electrically connected to and directly contacting the top electrode.

2. The semiconductor device according to claim 1, further comprising:
an inter-metal dielectric formed on the bottom metal layer, wherein the ReRAM cell structure and the upper metal layer are formed within the inter-metal dielectric.

3. The semiconductor device according to claim 2, wherein the inter-metal dielectric has a thickness of 2500-3500 Å.

4. The semiconductor device according to claim 2, further comprising:
a via formed in the inter-metal dielectric and located at a lateral side of the ReRAM cell structure, wherein the upper metal layer is electrically connected to the bottom metal layer through the via.

5. The semiconductor device according to claim 4, wherein the via has a height of 1000-1500 Å.

6. The semiconductor device according to claim 1, wherein the bottom electrode and the top electrode respectively comprise Ti, TiN, Ta, TaN, Pt, W, Al, Cu, or a combination thereof.

7. A semiconductor device, comprising:
a substrate;
a bottom metal layer located above the substrate;
a plurality of resistive random access memory (ReRAM) cell structures formed on the bottom metal layer, each of the ReRAM cell structures comprising:
a bottom electrode;
a memory cell layer formed on the bottom electrode; and
a top electrode formed on the memory cell layer;
an upper metal layer electrically connected to and directly contacting each of the top electrodes; and
an air gap formed between the adjacent ReRAM cell structures.

8. The semiconductor device according to claim 7, further comprising:
an inter-metal dielectric formed on the bottom metal layer, wherein the ReRAM cell structures and the upper metal layer are formed within the inter-metal dielectric.

9. The semiconductor device according to claim 8, wherein the inter-metal dielectric has a thickness of 2500-3500 Å.

10. The semiconductor device according to claim 8, further comprising:
a via formed in the inter-metal dielectric and located at a lateral side of the ReRAM cell structures, wherein the upper metal layer is electrically connected to the bottom metal layer through the via.

11. The semiconductor device according to claim 10, wherein the via has a height of 1000-1500 Å.

12. The semiconductor device according to claim 7, wherein each of the bottom electrodes and each of the top electrodes respectively comprise Ti, TiN, Ta, TaN, Pt, W, Al, Cu, or a combination thereof.

13. The semiconductor device according to claim 7, further comprising:
a spacer formed on two sides of each of the ReRAM cell structures.

14. A manufacturing method of a semiconductor device, comprising:
providing a substrate;
forming a bottom metal layer above the substrate;
forming a resistive random access memory (ReRAM) cell structure on the bottom metal layer, comprising:
forming a bottom electrode;
forming a memory cell layer on the bottom electrode;
forming a top electrode on the memory cell layer; and
forming a spacer on two sides of the bottom electrode, the memory cell layer and the top electrode; and
forming an upper metal layer electrically connected to and directly contacting the top electrode.

15. The manufacturing method of the semiconductor device according to claim 14, further comprising:
forming an inter-metal dielectric on the bottom metal layer, wherein the ReRAM cell structure and the upper metal layer are formed within the inter-metal dielectric.

16. The manufacturing method of the semiconductor device according to claim 15, wherein the inter-metal dielectric has a thickness of 2500-3500 Å.

17. The manufacturing method of the semiconductor device according to claim 15, further comprising:
forming a via in the inter-metal dielectric and located at a lateral side of the ReRAM cell structure, wherein the upper metal layer is electrically connected to the bottom metal layer through the via.

18. The manufacturing method of the semiconductor device according to claim 17, wherein the via has a height of 1000-1500 Å.

19. The manufacturing method of the semiconductor device according to claim 14, wherein forming the ReRAM cell structure further comprises:
forming a bottom electrode material;
forming a memory cell material on the bottom electrode material;
forming a top electrode material on the memory cell material; and
patterning the bottom electrode material, the memory cell material, and the top electrode material by an etching process for forming the bottom electrode, the memory cell layer, and the top electrode.

20. The manufacturing method of the semiconductor device according to claim 14, wherein forming the spacer comprises:
depositing a spacer material on the bottom electrode, the memory cell layer, and the top electrode; and
etching the spacer material for forming the spacer on the two sides of the bottom electrode, the memory cell layer, and the top electrode.
